(19) United States
(12) Patent Application Publication
(10) Pub. No.: US 2026/0059798 A1
(43) Pub. Date: Feb. 26, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chun-Yuan CHEN, Hsinchu (TW); Lo-Heng CHANG, Hsinchu (TW); Sheng-Tsung WANG, Hsinchu (TW); Huan-Chieh SU, Hsinchu (TW); Kuo-Cheng CHIANG, Hsinchu (TW); Chih-Hao WANG, Hsinchu (TW)

(73) Assignee: Taiwan Semiconductor Manufacturing Company, Ltd., Hsinchu (TW)

(21) Appl. No.: 18/815,480

(22) Filed: Aug. 26, 2024

(51) Int. Cl. H01L 29/417; H01L 21/285; H01L 29/06; H01L 29/423; H01L 29/66; H01L 29/775; H01L 29/786

(52) U.S. Cl. CPC H10D 30/6729; H01L 21/28518; H10D 30/014; H10D 30/43; H10D 30/6735; H10D 30/6757; H10D 62/121; H10D 64/017

(57) ABSTRACT

A semiconductor device including a first epitaxial source/drain feature, a second epitaxial source/drain feature, two or more semiconductor layers electrically connected to the first and second epitaxial source/drain features, a backside source/drain contact, and a bottom dielectric layer is provided. The backside source/drain contact is disposed on one side of the first epitaxial source/drain feature, the backside source/drain contact is electrically connected to a bottom surface of the first epitaxial source/drain feature. The bottom dielectric layer is disposed on a backside of the semiconductor layers, and the bottom dielectric layer electrically isolates the backside source/drain contact from the semiconductor layers.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1D and 2 to 5 are perspective views of various stages for fabricating a semiconductor device according to embodiments of the present disclosure.

FIGS. 6A to 6J are schematic diagrams illustrating a method of manufacturing a backside source/drain contact according to an embodiment of the present disclosure.

FIG. 7 is a schematic cross-sectional view of a semiconductor device according to another embodiment of the disclosure.

FIG. 8 is a schematic three-dimensional view of a semiconductor device according to an embodiment of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure can pattern a gate all around (GAA) transistor structure by any suitable method. For example, one or more photolithography processes may be used to pattern the structure, including dual patterning processes or multiple patterning processes. Typically, a dual or multi-patterning process combines a photolithography process with a self-aligned process, allowing the creation of patterns with, for example, smaller pitches than achievable pitches using a single direct photolithography process. For example, in one embodiment, a sacrificial layer is formed over a substrate and patterned using a photolithography process. Spacers are formed along the patterned sacrificial layer using a self-aligned process. The sacrificial layer is then removed, and the remaining spacers can then be used to pattern the GAA structure.

The present disclosure relates to a semiconductor device and a method of manufacturing the same. More specifically, some embodiments of the present disclosure relate to semiconductor devices including improved epitaxial bottom isolation structures. The semiconductor devices proposed herein include p-type semiconductor devices or n-type semiconductor devices. Additionally, a semiconductor device may have one or more channel regions (e.g., nanowires) associated with a single continuous gate structure, or multiple gate structures. Those skilled in the art may recognize other examples of semiconductor devices that may benefit from aspects of the present disclosure.

Although embodiments of the present disclosure relate to nanostructured channel field effect transistors (FETs) (including horizontal gate all around (HGAA) field effect transistors, vertical gate all around (VGAA) field effect transistors, etc.), some aspects of the disclosure may be implemented in other processes and/or other devices, such as planar field effect transistors, fin field effect transistors (Fin-FET), and other suitable devices. Those skilled in the art will readily appreciate that other modifications are contemplated within the scope of this disclosure.

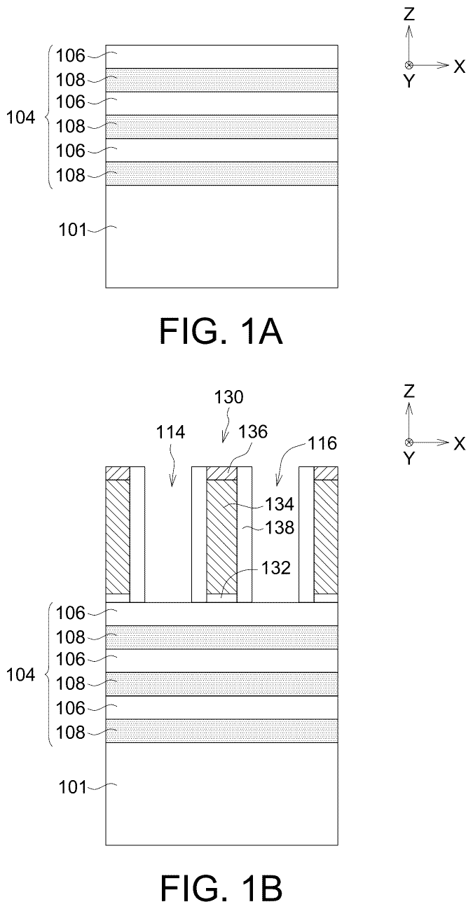

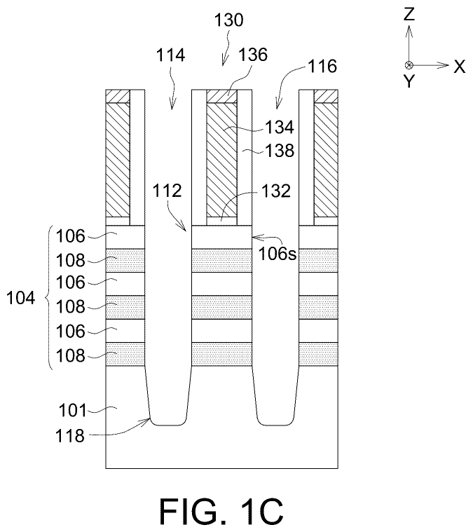

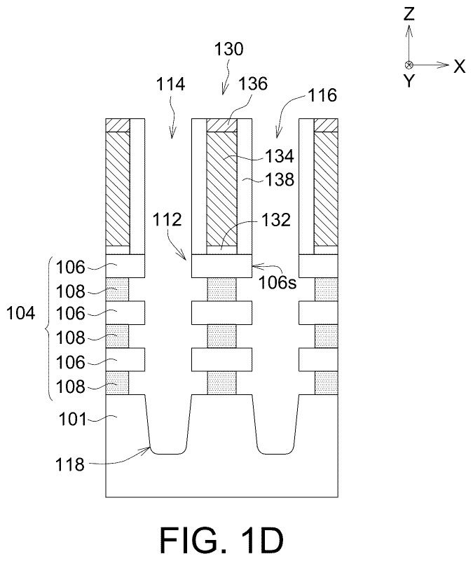

FIGS. 1A to 1D and 2 to 5 are perspective views of various stages for manufacturing a semiconductor device 100 according to embodiments of the present disclosure. It will be appreciated that for additional embodiments of the method, additional steps may be provided before, during, and after the processes illustrated in FIGS. 1A-5, and some of the steps described below may be replaced or eliminated. The sequence of steps/processes is unrestricted and interchangeable.

As shown in FIG. 1A, semiconductor device 100 includes a stack of semiconductor layers 104 formed over a substrate 101. The substrate 101 may be a semiconductor substrate. The substrate 101 may include single crystal semiconductor materials, such as but not limited to, silicon (Si), germanium (Ge), silicon germanium (SiGe), gallium arsenide (GaAs), indium antimonide (InSb), gallium phosphide (GaP), Gallium antimonide (GaSb), indium aluminum arsenide (InAlAs), indium gallium arsenide (InGaAs), gallium antimony phosphide (GaSbP), gallium arsenide antimonide (GaAsSb) and indium phosphide (InP). In some embodiments, the substrate 101 is a silicon-on-insulator (SOI) substrate having an insulating layer (not shown) disposed between two silicon layers for reinforcement. In one aspect, the insulating layer is an oxygen-containing layer.

The stack of semiconductor layers 104 includes semiconductor layers made of different materials to facilitate the formation of nanostructured channels in multi-gate devices such as nanostructured field effect transistors. In some embodiments, the stack of semiconductor layers 104 includes a first semiconductor layer 106 and a second semiconductor layer 108. In some embodiments, the stack of semiconductor layers 104 includes alternating first semiconductor layers 106 and second semiconductor layers 108, and the first semiconductor layers 106 and the second semiconductor layers 108 are disposed parallel to each other. The first semiconductor layer 106 and the second semiconductor layer 108 are made of semiconductor materials with different etching selectivities and/or different oxidation rates. For example, the first semiconductor layer 106 can be made of Si, and the second semiconductor layer 108 can be made of SiGe. In some examples, first semiconductor layer 106 may be made of germanium-doped silicon, and second semiconductor layer 108 may be made of SiGe. In some examples, first semiconductor layer 106 can be made of SiGe and second semiconductor layer 108 can be made of Si. In some embodiments, the first semiconductor layer 106 can be made of SiGe having a first germanium concentration range, and the second semiconductor layer 108 can be made of SiGe having a second germanium concentration range that is lower or greater than the first germanium concentration range. Alternatively, in some embodiments, any one of the first semiconductor layer 106 and the second semiconductor layer 108 may be or include other materials, such as Ge, SiC, GeAs, GaP, InP, InAs, InSb, GaAsP, AlInAs, AlGaAs, InGaAs, GaInP, GaInAsP or any combination thereof.

The thickness of the first semiconductor layer 106 and the second semiconductor layer 108 may vary depending on application and/or device performance considerations. In some embodiments, each of the first semiconductor layer 106 and the second semiconductor layer 108 has a thickness between about 5 nm and about 30 nm. In other embodiments, each of the first semiconductor layer 106 and the second semiconductor layer 108 has a thickness between about 10 nm and about 20 nm. In some embodiments, each of the first semiconductor layer 106 and the second semiconductor layer 108 has a thickness between about 6 nm and about 12 nm. Each second semiconductor layer 108 may have a thickness equal to, smaller than, or larger than that of the first semiconductor layer 106. The second semiconductor layer 108 may eventually be removed and used to define the vertical distance between adjacent channels of the semiconductor device structure 100.

The first semiconductor layer 106 or a portion thereof may form the nanostructured channels of the semiconductor device 100 in a later manufacturing stage. In one embodiment, the term “nanostructure” is used herein to mean any portion of a material that has a nanometer or even micron dimension and has an elongated shape, regardless of the cross-sectional shape of the portion. Accordingly, this term refers to elongated material portions and bundled or rod-like material portions of circular and substantially circular cross-sections, including, for example, cylindrical or substantially rectangular cross-sections. The nanostructure channels of semiconductor device 100 may be surrounded by gate electrodes. Semiconductor device 100 may include nanostructured transistors. Nanostructured transistors can be called nanowire transistors, gate-surround transistors, multi-bridge channel (MBC) transistors, or any transistor with a gate electrode surrounding a channel. The use of first semiconductor layer 106 to define one or more channels of semiconductor device 100 is discussed further below.

The first semiconductor layer 106 and the second semiconductor layer 108 are formed by any suitable deposition process, such as an epitaxial process. For example, the stack of semiconductor layers 104 may be epitaxially grown by a molecular beam epitaxy (MBE) process, a metalorganic chemical vapor deposition (MOCVD) process, and/or other suitable epitaxy growth processes. Although three first semiconductor layers 106 and three second semiconductor layers 108 are alternately arranged as shown in FIG. 1A, it should be understood that according to the predetermined number of nanostructure channels of each field effect transistor, any number of first semiconductor layers 106 and second semiconductor layers 108 may be formed in the stack of the semiconductor layer 104. For example, the number of first semiconductor layers 106 (i.e., the number of channels) may be between 2 and 8.

In some embodiments, a hard mask layer (not shown) formed on the stack of semiconductor layers 104 is patterned using multiple patterning steps including photolithography and etching processes. The etching process may include dry etching, wet etching, reactive ion etching (RIE) and/or other suitable processes. The photolithography process may include forming a photoresist layer (not shown) over the hard mask layer, exposing the photoresist layer to the pattern, performing a post-exposure bake process, and developing the photoresist layer to form a masking element of the photoresist layer. In some embodiments, an electron beam (e-beam) lithography process may be used to pattern the photoresist layer to form the masking element. The etching process creates trenches in the unprotected areas through the hard mask layer, through the stack of semiconductor layers 104 and into the substrate 101, leaving a plurality of vertically extending fin structures. The trenches extend along the X direction. The trenches may be etched using dry etching (e.g., RIE), wet etching, and/or combinations thereof.

In FIG. 1B, one or more sacrificial gate structures 130 are formed over the semiconductor device 100. The sacrificial gate structure 130 is formed over a portion of the fin structure 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 can be formed by sequentially depositing a blanket layer of the sacrificial gate dielectric layer 132, the sacrificial gate electrode layer 134, and the mask layer 136, and then these layers are patterned into a sacrificial gate structure 130. Gate spacers 138 are then formed on the sidewalls of the sacrificial gate structure 130. For example, gate spacers 138 may be formed by conformally depositing one or more layers of gate spacers 138 and anisotropically etching the one or more layers. Although one sacrificial gate structure 130 is shown in the figures, in some embodiments, two or more sacrificial gate structures 130 may be configured along the X direction.

The sacrificial gate dielectric layer 132 may include one or more layers of dielectric material, such as a silicon oxide-based material. The sacrificial gate electrode layer 134 may include silicon, such as polycrystalline silicon or amorphous silicon. The mask layer 136 may include more than one layer, such as an oxide layer and a nitride layer. The gate spacers 138 may be made of a dielectric material such as silicon oxide, silicon nitride, silicon carbide, silicon oxynitride (SiON), silicon nitride carbide (SiCN), silicon oxycarbide (SiCO), silicon oxynitride oxide (SiOCN) and/or combinations thereof.

In FIG. 1C, the portion of the fin structure 112 covered by the sacrificial gate electrode layer 134 of the sacrificial gate structure 130 serves as a channel region of the semiconductor device 100. Fin structures 112 partially exposed on opposite sides of sacrificial gate structure 130 define source/drain (S/D) regions 114, 116 of semiconductor device 100. In some cases, some source/drain regions 114, 116 may be shared between various transistors. For example, each of the source/drain regions 114, 116 may be connected together and implemented as a multifunctional transistor.

In FIG. 1D, edge portions of each second semiconductor layer 108 of the stack of semiconductor layers 104 are removed horizontally along the X direction. An edge portion of the second semiconductor layer 108 is removed to form a cavity. In some embodiments, a portion of the second semiconductor layer 108 is removed through a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The removal of edge portions of the second semiconductor layers 108 expose a portion of side surfaces of the first semiconductor layers 106 along the X direction.

In FIG. 1D, after removing the edge portions of the second semiconductor layers 108, a dielectric layer is deposited in the cavity to form dielectric spacers 144 (or inner spacers). The dielectric spacers 144 may be made of a low-k dielectric material, such as SiON, SiCN, SiOC, SiOCN, or SiN. In some embodiments, dielectric spacers 144 are formed from a material having a dielectric constant in the range of 3.5 to 5.5. The dielectric spacers 144 may be formed by atomic layer deposition, pulsed plasma chemical vapor deposition, or any suitable deposition process. The remaining second semiconductor layers 108 cover between the dielectric spacers 144 along the X direction. The end portion of the dielectric spacer 144 beneath the first semiconductor layer 106 may have a flat surface 144f that is substantially flush with the outer surfaces 106s of the first semiconductor layers 106.

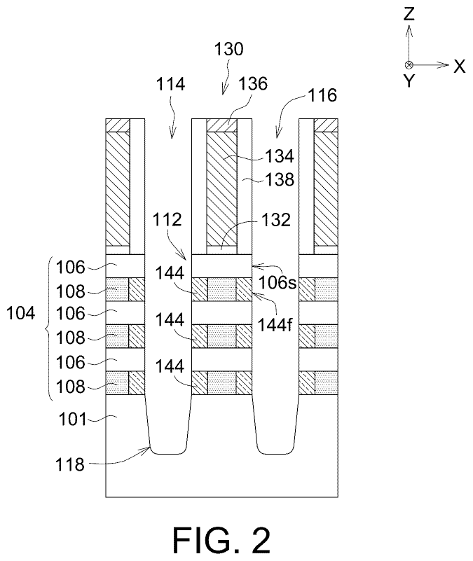

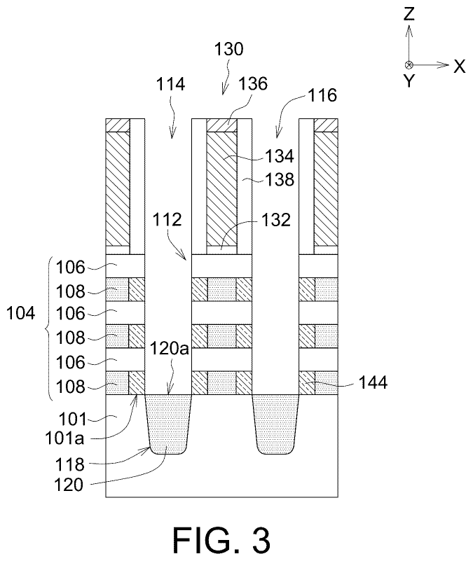

In FIG. 2, the bottom portion below the source/drain regions 114, 116 is removed, such as etched, to form a trench 118. The trench 118 can be formed before the formation of inner spacers 144 as shown in FIGS. 1C and 1D. In another embodiment, the trench 118 can be formed after the formation of inner spacers 144. The etching process may be dry etching such as RIE, NBE, or wet etching such as using tetramethylammonium hydroxide (TMAH), ammonium hydroxide (NH₄OH) or any suitable etchant to make the bottom portions of the source/drain regions 114, 116 have deep trenches 118. In FIG. 3, a semiconductor material 120 (e.g., silicon germanium or silicon) may be further deposited or refilled in the deep trench 118 inside the substrate 101. The top surface 120a of semiconductor material 120 may be coplanar with or lower than top surface 101a of substrate 101.

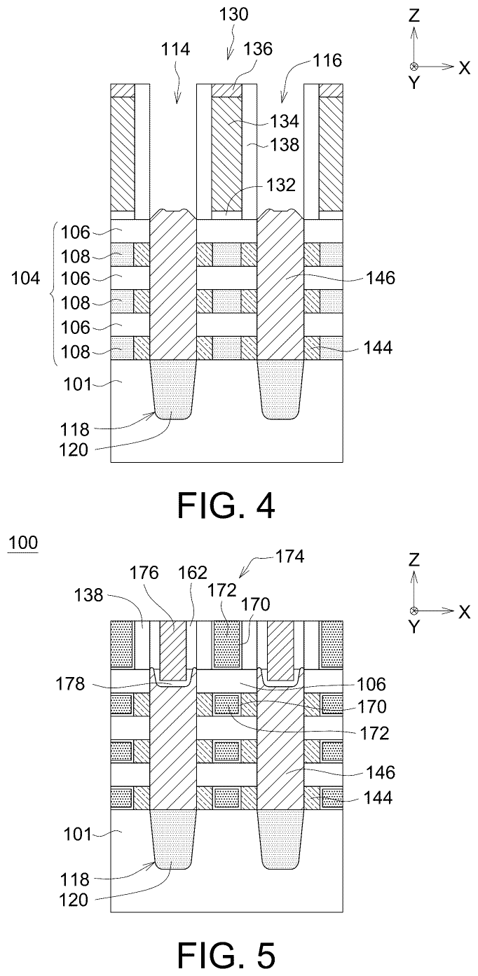

Referring to FIG. 4, in subsequent processes, epitaxial source/drain features 146 are formed on the top surface 120a of the semiconductor material s 120. The epitaxial source/drain features 146 may be made of one or more layers of Si, SiP, SiC, and SiCP for n-channel FETs, or Si, SiGe, Ge for p-type channel FETs. For p-type channel FETs, p-type dopants such as boron may also be included in the epitaxial source/drain features 146. Epitaxial source/drain features 146 may be formed by epitaxial growth methods using chemical vapor deposition, atomic layer deposition, or molecular beam epitaxy. The epitaxial source/drain features 146 may be grown vertically and horizontally to form facets, which may correspond to crystallographic planes of the material used for substrate 101. In some cases, epitaxial source/drain features 146 may be grown and merged with adjacent epitaxial source/drain features 146. In some embodiments, prior to forming epitaxial source/drain features 146, a source/drain pre-clean process may be performed to remove native oxide formed on first semiconductor layer 106 and dielectric spacers 144. The source/drain pre-cleaning process may be an inert gas sputtering process (e.g., argon sputtering) or a plasma-based cleaning process. In one embodiment, the source/drain pre-clean process is a SiCoNi process that uses remote plasma to generate ammonium fluoride (NH₄F) etchant from nitrogen trifluoride (NF₃) and ammonia (NH₃) to minimize damage to semiconductor device 100.

In one example shown in FIG. 4, one of a pair of epitaxial source/drain features 146 disposed on one side of the sacrificial gate structure 130 is designated as the source feature (source terminal), and the other of the pair of epitaxial source/drain features 146 disposed on the other side of the sacrificial gate structure 130 is designated as the drain feature (drain terminal). The source feature (source terminal) and the drain feature (drain terminal) are connected by a channel layer (e.g., first semiconductor layer 106). The epitaxial source/drain features 146 contact the first semiconductor layer 106 beneath the sacrificial gate structure 130. In some cases, epitaxial source/drain features 146 may grow beyond the topmost semiconductor channel (i.e., the first semiconductor layer 106 below the sacrificial gate structure 130) to contact the gate spacers 138. The second semiconductor layer 108 beneath the sacrificial gate structure 130 is separated from the epitaxial source/drain features 146 by dielectric spacers 144.

In some embodiments, a contact etch stop layer (CESL) 162 is conformally formed on the exposed surface of the semiconductor device 100. The contact etch stop layer 162 covers the exposed surface of sacrificial gate structure 130, the sidewalls of epitaxial source/drain features 146, and the stack of semiconductor layers 104. The CESL 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may formed by CVD, PECVD, ALD or any suitable deposition technique. Next, a first interlayer dielectric layer (ILD) is formed on the contact etch stop layer 162 over the semiconductor device structure 100. The material of the first interlayer dielectric layer may include compounds including Si, O, C, and/or H, such as silicon oxide, ethyl orthosilicate oxide, SiCOH, and SiOC. Organic materials such as polymers can also be used for the first interlayer dielectric layer. The first interlayer dielectric layer may be deposited by a PECVD process or other suitable deposition techniques. In some embodiments, after forming the first interlayer dielectric layer, the semiconductor device structure 100 may undergo a thermal process to anneal the first interlayer dielectric layer.

After forming the first interlayer dielectric layer, a planarization operation such as chemical mechanical polishing is performed on the semiconductor device 100 until the sacrificial gate electrode layer 134 is exposed. Next, the sacrificial gate structure 130 and the second semiconductor layers 108 are removed. Removing the sacrificial gate structure 130 and the second semiconductor layer 108 forms an opening between the gate spacers 138 and the first semiconductor layer 106. The interlayer dielectric layer protects the epitaxial source/drain features 146 during the removal process. The sacrificial gate structures 130 may be removed using plasma dry etching and/or wet etching. The sacrificial gate electrode layer 134 may first be removed by any suitable process, such as dry etching, wet etching, or a combination thereof. The sacrificial gate dielectric layer 132 is then removed by performing any suitable process (such as dry etching, wet etching, or a combination thereof). In some embodiments, a wet etchant, such as a tetramethylammonium hydroxide (TMAH) solution, may be used to selectively remove the sacrificial gate electrode layer 134 but not the gate spacers 138, the interlayer dielectric layer, and the contact etch stop layer 162.

In some embodiments, a selective wet etching process may be used to remove the second semiconductor layers 108. In the case where the second semiconductor layers 108 are made of SiGe and the first semiconductor layers 106 are made of Si, the chemicals used in the selective wet etch process remove the SiGe while not substantially affecting the Si (gate spacers 138 and dielectric material of dielectric spacers 144). In one embodiment, a wet etchant such as, but not limited to, hydrofluoric acid (HF), nitric acid (HNO₃), hydrochloric acid (HCl), phosphoric acid (H₃PO₄), a dry etchant such as a fluorine-based (e.g., F₂) or chlorine-based gas (e.g., Cl₂)) or any suitable isotropic etchant to remove the second semiconductor layers 108.

In FIG. 5, after forming the nanostructure channels (i.e., the exposed first semiconductor layers 106), a gate dielectric layer 170 is formed to surround the first semiconductor layers 106, and the gate electrode layer 172 is formed on the gate dielectric layer 170. The gate dielectric layer 170 and the gate electrode layer 172 may be collectively referred to as the gate structure 174. In some embodiments, an interfacial layer (IL) (not shown) is formed between the gate dielectric layer 170 and the exposed surface of the first semiconductor layers 106. In such cases, the interface layer may also be formed on the well portion of the substrate 101. The interface layer may include or be made of oxygen-containing materials or silicon-containing materials, such as silicon oxide, silicon oxynitride, oxynitride, hafnium silicate, and the like. The interface layer can be formed by CVD, ALD, cleaning process or any suitable process. In some embodiments, gate dielectric layer 170 includes one or more layers of dielectric materials, such as silicon oxide, silicon nitride, high-k dielectric materials, other suitable dielectric materials, and/or combinations thereof. Examples of high-k dielectric materials include HfO₂, HfSiO, HfSiON, HfTaO, HfTiO, HfZrO, zirconium oxide, alumina, titanium oxide, hafnium dioxide-aluminum oxide (HfO₂—Al₂O₃) alloy, and other suitable high-k dielectric materials Constant dielectric materials and/or combinations thereof. The gate dielectric layer 170 may be formed by CVD, ALD, or any suitable deposition technique.

The gate electrode layer 172 may include one or more layers of conductive materials, such as polycrystalline silicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials and/or any combination thereof. The gate electrode layer 172 may be formed by CVD, ALD, electroplating or other suitable deposition techniques. The gate electrode layer 172 may also be deposited over the upper surface of the first interlayer dielectric layer. Next, the gate dielectric layer 170 and the gate electrode layer 172 formed over the first interlayer dielectric layer are removed by using, for example, chemical mechanical polishing until the top surface of the first interlayer dielectric layer is exposed.

In FIG. 5, source/drain contacts 176 are formed in the first interlayer dielectric layer. Prior to forming the source/drain contacts 176, contact openings are formed in the first interlayer dielectric layer to expose the epitaxial source/drain features 146. Contact openings are formed through various layers, including the first interlayer dielectric layer and contact etch stop layer 162, using suitable photolithography and etching techniques to expose the epitaxial source/drain features 146. In some embodiments, upper portions of epitaxial source/drain features 146 are etched.

After forming the contact openings, a silicide layer 178 is formed over the epitaxial source/drain features 146. The silicide layer 178 electrically couples epitaxial source/drain features 146 to subsequently formed source/drain contacts 176. The silicide layer 178 may be formed by depositing a metal source layer over epitaxial source/drain features 146 and performing a rapid thermal annealing process. During the rapid anneal process, a portion of the metal source layer over the epitaxial source/drain features 146 reacts with the silicon in the epitaxial source/drain features 146 to form a silicide layer 178. Next, the unreacted portion of the metal source layer is removed. In some embodiments, silicide layer 178 is made of metal or metal alloy silicide, and the metal includes noble metals, refractory metals, rare earth metals, alloys thereof, or combinations thereof. Next, conductive material is formed in the contact openings and source/drain contacts 176 are formed. The conductive material may be made of materials including one or more of Ru, Mo, Co, Ni, W, Ti, Ta, Cu, Al, TiN, and TaN. Although not shown, prior to forming the source/drain contacts 176, a barrier layer (e.g., TiN, TaN, or the like) may be formed on the sidewalls in the contact openings. Next, a planarization process such as chemical mechanical polishing is performed to remove excess deposited contact material and expose the top surface of the gate electrode layer 172.

It should be understood that the semiconductor device 100 may undergo further complementary metal oxide semiconductor (CMOS) processes and/or back-end-of-line (BEOL) processes to form various features, such as transistors, contacts/vias, interconnect metal layers, dielectric layers, passivation layers, etc. Semiconductor device 100 may also include backside source/drain contacts 126 on the backside of substrate 101 (see description below) such that the source or drain of epitaxial source/drain feature 146 is connected to the backside power rail (e.g., positive voltage VDD or negative voltage VSS) through the backside source/drain contacts 126.

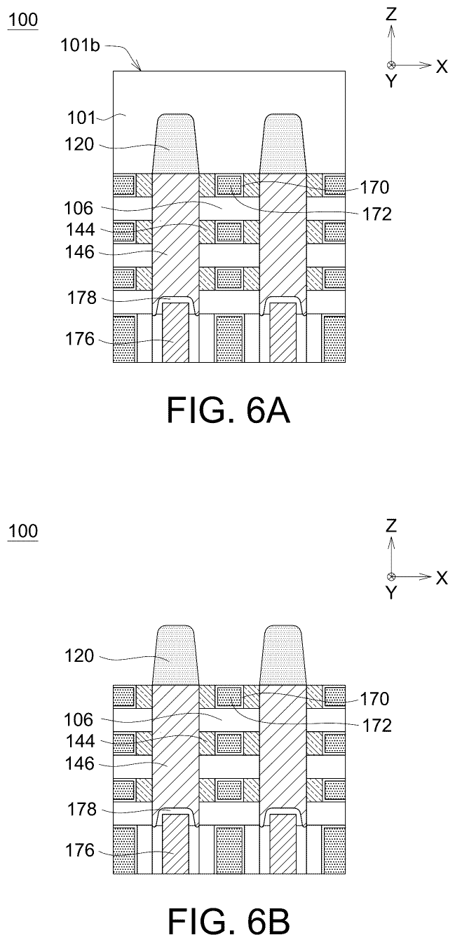

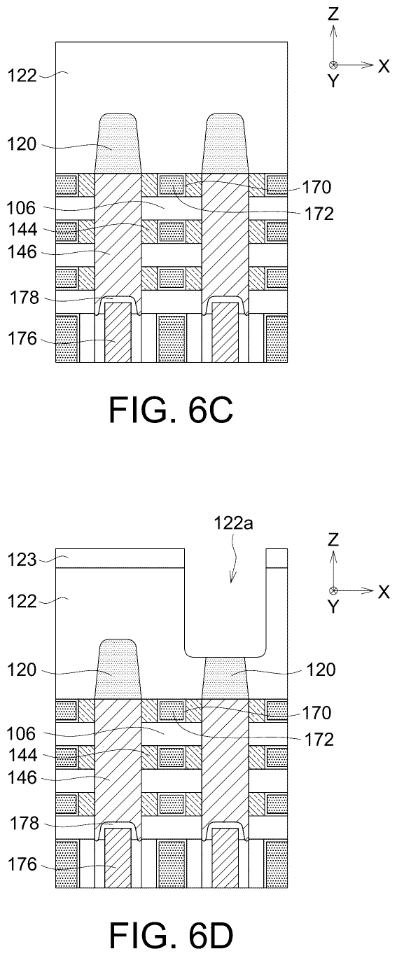

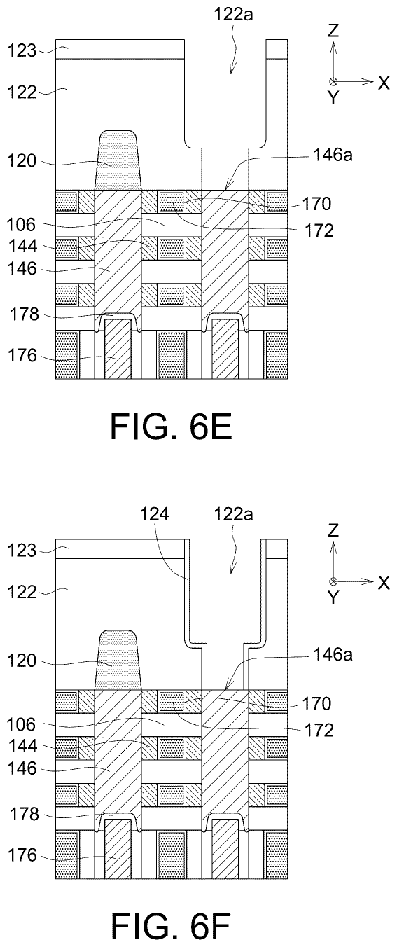

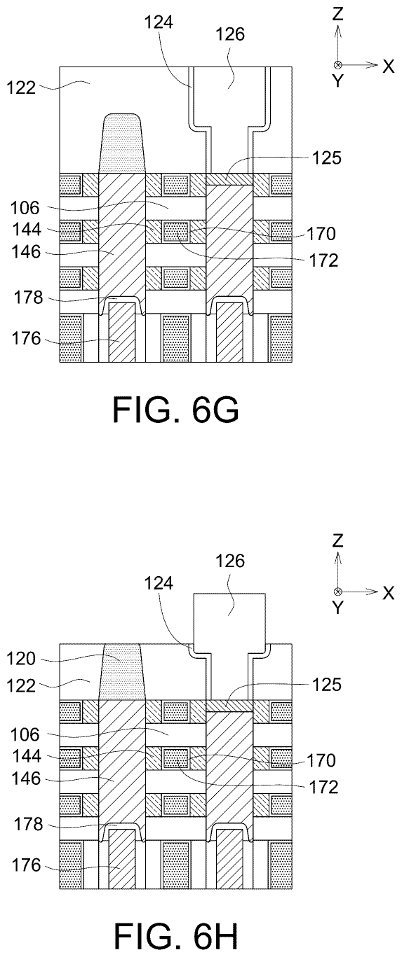

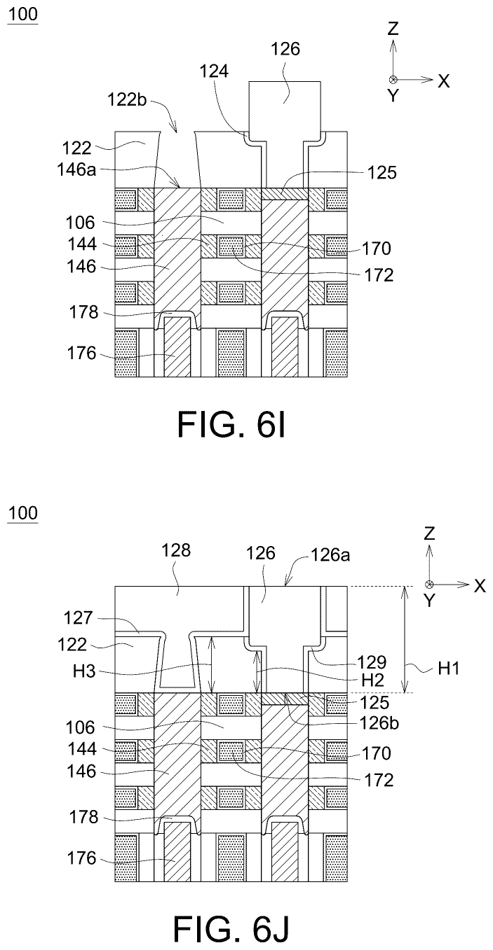

For a method of fabricating backside source/drain contacts on the backside of substrate 101, please refer to FIGS. 6A to 6J. First, in FIG. 6A, the backside 101b of the substrate 101 is placed upward, with the source/drain contacts 176 facing downward. In FIG. 6B, the substrate 101 is etched to expose semiconductor features (such as semiconductor material 120) located at the bottom of semiconductor device 100. In FIG. 6C, a bottom dielectric layer 122 is deposited on the semiconductor device 100, and the bottom dielectric layer 122 covers the semiconductor features (such as semiconductor material 120). In FIG. 6D, suitable photolithography and etching techniques are used to penetrate the bottom dielectric layer 122 to form a bottom contact opening 122a. The size and position of the bottom contact opening 122a can be defined by the patterned hard mask layer 123 covered on the bottom dielectric layer 122. In FIG. 6D, a wet etchant can be passed into the bottom contact opening 122a to remove a portion of the conductive member using a wet etching process. Then, in FIG. 6E, an anisotropic etching process, such as RIE, NBE, dry etching, wet etching, or combinations thereof, is used to remove the conductive element to form a cavity and expose the bottom surface 146a of the epitaxial source/drain feature 146 in the bottom contact opening 122a.

In FIG. 6F, a barrier layer 124 (e.g., TiN, TaN, or the like) is deposited in the cavity to form spacers on the sidewalls in the bottom contact opening 122a. The barrier layer 124 may be formed by atomic layer deposition, pulsed plasma chemical vapor deposition, or any suitable deposition process.

In FIG. 6G, a silicide layer 125 is formed over the epitaxial source/drain features 146 after forming the bottom contact opening 122a. The silicide layer 125 electrically couples epitaxial source/drain features 146 to subsequently formed backside source/drain contact 126. The Silicide layer 125 may be formed by depositing a metal source layer over epitaxial source/drain features 146 and performing a rapid thermal annealing process. During the rapid anneal process, a portion of the metal source layer over the epitaxial source/drain features 146 reacts with the silicon in the epitaxial source/drain features 146 to form the silicide layer 125. Unreacted portions of the metal source layer are then removed. In some embodiments, the silicide layer 125 is made of metal or metal alloy silicide, and the metal includes noble metals, refractory metals, rare earth metals, alloys thereof, or combinations thereof. Next, conductive material is formed in the contact openings and the backside source/drain contact 126 is formed. The conductive material may be made of materials including one or more of Ru, Mo, Co, Ni, W, Ti, Ta, Cu, Al, TiN, and TaN. Next, a planarization process such as chemical mechanical polishing is performed to remove excess deposited contact material and expose the surface of the backside source/drain contact 126.

In FIG. 6H, the bottom dielectric layer 122 is etched to expose the backside source/drain contact 126 and adjacent another semiconductor feature (semiconductor material 120). In one embodiment, at least one wet etching process is performed for the bottom dielectric layer 122 until the semiconductor material 120 (e.g., SiGe) is exposed. The wet etching process may be controlled by a controller that analyzes thickness measurements of the bottom dielectric layer 122 and dynamically and instantaneously generates etch recipes for each etch step. In FIG. 6I, the semiconductor material 120 can be removed using suitable photolithography and etching techniques, such as an anisotropic etching process (RIE, NBE, dry etching, wet etching, or a combination thereof) to form a cavity and expose the bottom surface 146a of the epitaxial source/drain feature 146 in the bottom insulating opening 122b.

In FIG. 6J, a liner layer 127 is formed on the bottom surface and sidewalls in the bottom insulating opening 122b, the exposed surface of the bottom dielectric layer 122 and the side surface of the backside source/drain contact 126. The liner layer 127 may include silicon-containing materials, such as silicon oxide, silicon nitride, silicon oxynitride, silicon carbide, etc., and may be deposited using CVD, PVD, ALD, or other suitable methods. Next, an isolation insulating material 128 is deposited (or refilled) on the liner layer 127, and a planarization process such as chemical mechanical polishing is performed to remove the over-deposited insulating material and expose the bottom surface 126a of the backside source/drain contact 126. The isolation insulating material 128 may include silicon-containing materials, such as silicon oxide, silicon nitride, silicon oxynitride, etc., which may be deposited using CVD, PVD, ALD, or other suitable methods.

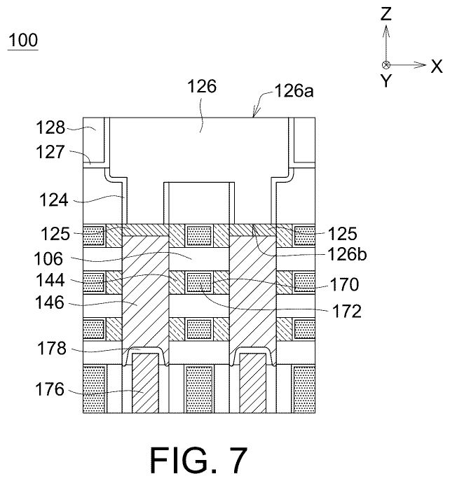

In some embodiments, the backside source/drain contact 126 is formed by, for example, a conductive material of T-shaped profile, and the conductive material can be formed on the silicide layer 125 in a self-aligned manner. Referring to FIG. 7, in another embodiment, the backside source/drain contact 126 can be formed on two adjacent silicon compound layers 125 in a self-aligned manner, so that the backside source/drain contact 126 can be connected to two epitaxial source/drain features 146. The backside source/drain contact 126 has, for example, a π-shaped profile so that the backside source/drain contact 126 has a relatively low capacitance value.

The area of the bottom surface 126a of the backside source/drain contact 126 is relatively larger than the area of the top surface 126b, and the bottom surface 126a has a first height H1 relative to the top surface 126b. In addition, the backside source/drain contact 126 has a convex platform 129, and the surface of the convex platform 129 has a second height H2 relative to the top surface 126b, and the second height H2 is less than the first height H1. In addition, the bottom surface of the bottom dielectric layer 122 has a third height H3 relative to the top surface 126b of the backside source/drain contact 126. The third height H3 is greater than the second height H2 but less than the first height H1. The third height H3 is, for example, between 10 nm and 30 nm. The second height H2 is, for example, between 0 nm and 25 nm.

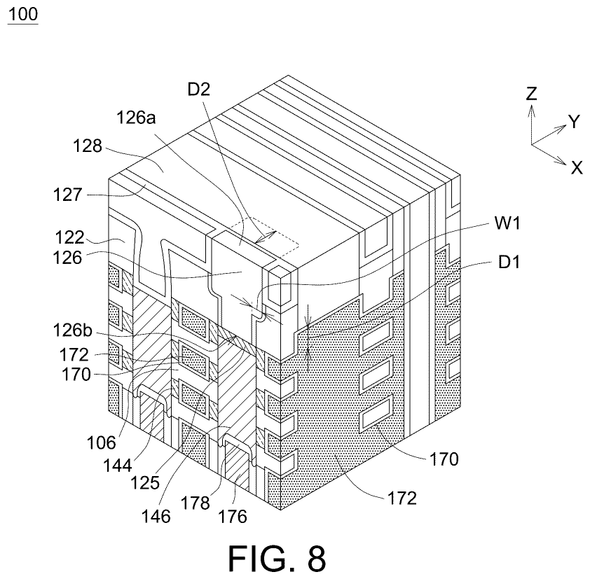

Referring to FIG. 8, the profile of the bottom surface 126a of the backside source/drain contact 126 in the Y-axis direction can extend a distance D2 into the isolation insulating material 128 to increase the bottom area of the backside source/drain contact 126, and the distance D2 is about 0 to 20nm. In addition, the metal gate 172 may extend a distance D1 into the bottom dielectric layer 122 in the Z-axis direction relative to the top surface 126b of the backside source/drain contact 126, and the distance D1 is approximately 0 nm to 25 nm. In addition, referring to FIG. 8, the convex platform 129 of the backside source/drain contact 126 can extend a width W1 relative to the top surface 126b in the X-axis direction, and the width W1 is about 0 nm to 25 nm. Through the above structure, the backside source/drain contact 126 has a lower capacitance value, and the insulation of the bottom dielectric layer 122 is better than that of silicon substrate, thereby preventing leakage from the bottom of the epitaxy source/drain features 146.

The present disclosure is directed to a semiconductor device including improved epitaxial bottom isolation structures. The silicon substrate is replaced by a bottom dielectric layer for lower capacitance, and the backside source/drain contact is formed on one or more silicide layers of the epitaxial source/drain features in a self-aligned manner. Therefore, the backside source/drain contact has a lower capacitance value, and the insulation of the bottom dielectric layer is better than that of silicon substrate, thereby preventing leakage from the bottom of the epitaxy source/drain features.

According to some embodiments of the present disclosure, a semiconductor device including a first epitaxial source/drain feature, a second epitaxial source/drain feature, two or more semiconductor layers electrically connected to the first and second epitaxial source/drain features, a backside source/drain contact, and a bottom dielectric layer is provided. The backside source/drain contact is disposed on one side of the first epitaxial source/drain feature, the backside source/drain contact is electrically connected to a bottom surface of the first epitaxial source/drain feature. The bottom dielectric layer is disposed on a backside of the semiconductor layers, and the bottom dielectric layer electrically isolates the backside source/drain contact from the semiconductor layers.

According to some embodiments of the present disclosure, a semiconductor device including a first epitaxial source/drain feature, a second epitaxial source/drain feature, two or more semiconductor layers electrically connected to the first epitaxial source/drain feature and the second epitaxial source/drain feature, a backside source/drain contact, and a bottom dielectric layer is provided. The backside source/drain contact is disposed on one side of the first and second epitaxial source/drain features, the backside source/drain contact is electrically connected to a bottom surface of the first epitaxial source/drain feature and a bottom surface of the second epitaxial source/drain feature. The bottom dielectric layer is disposed on a backside of the semiconductor layers, and the bottom dielectric layer electrically isolates the backside source/drain contact from the semiconductor layers.

According to some embodiments of the present disclosure, a method of manufacturing a semiconductor device is provided. A first epitaxial source/drain feature is formed over a substrate. A second epitaxial source/drain feature is formed over the substrate. Two or more semiconductor layers are formed between the first epitaxial source/drain feature and the second epitaxial source/drain feature. The substrate is removed to expose a backside of the first and second epitaxial source/drain features. A bottom dielectric layer is formed on the backside of the first and second epitaxial source/drain features.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first epitaxial source/drain feature;
a second epitaxial source/drain feature;
two or more semiconductor layers electrically connected between the first epitaxial source/drain feature and the second epitaxial source/drain feature;
a backside source/drain contact disposed on one side of the first epitaxial source/drain feature, the backside source/drain contact electrically connected to a bottom surface of the first epitaxial source/drain feature; and
a bottom dielectric layer disposed on a backside of the semiconductor layers, and the bottom dielectric layer electrically isolates the backside source/drain contact from the semiconductor layers.

2. The semiconductor device of claim 1, further comprising a gate dielectric layer surrounding each of the two or more semiconductor layers.

3. The semiconductor device of claim 2, further comprising at least one gate electrode layer located between two adjacent semiconductor layers of the semiconductor layers, and the gate dielectric layer surrounds the gate electrode layer.

4. The semiconductor device of claim 1, further comprising a source/drain contact disposed on another side of the first epitaxial source/drain feature, the source/drain contact being electrically connected to a top surface of the first epitaxial source/drain feature.

5. The semiconductor device of claim 1, further comprising an isolation insulating material filled in a backside of the second epitaxial source/drain feature, the isolation insulating material covering the bottom dielectric layer.

6. The semiconductor device of claim 1, wherein the backside source/drain contact has a platform, and a height of the platform relative to a top surface of the backside source/drain contact is less than a height of the bottom dielectric layer.

7. The semiconductor device of claim 1, wherein the backside source/drain contact has a T-shaped profile.

8. A semiconductor device, comprising:
a first epitaxial source/drain feature;
a second epitaxial source/drain feature;
two or more semiconductor layers electrically connected between the first epitaxial source/drain feature and the second epitaxial source/drain feature;
a backside source/drain contact disposed on one side of the first and second epitaxial source/drain features, the backside source/drain contact being electrically connected to a bottom surface of the first epitaxial source/drain feature and a bottom surface of the second epitaxial source/drain feature; and
a bottom dielectric layer is disposed on a backside of the semiconductor layers, and the bottom dielectric layer electrically isolates the backside source/drain contact from the semiconductor layers.

9. The semiconductor device of claim 8, further comprising a source/drain contact disposed on another side of the first epitaxial source/drain feature, and the source/drain contact being electrically connected to a top surface of the first epitaxial source/drain feature.

10. The semiconductor device of claim 8, further comprising an isolation insulating material filled in a backside of the bottom dielectric layer, and the isolation insulating material covering the bottom dielectric layer.

11. The semiconductor device of claim 8, wherein the backside source/drain contact has a platform, and a height of the platform relative to a top surface of the backside source/drain contact is less than a height of the bottom dielectric layer.

12. The semiconductor device of claim 8, wherein the backside source/drain contact has a π-shaped profile.

13. A method of manufacturing a semiconductor device, comprising:
forming a first epitaxial source/drain feature over a substrate;
forming a second epitaxial source/drain feature over the substrate;
forming two or more semiconductor layers between the first epitaxial source/drain feature and the second epitaxial source/drain feature;
removing the substrate to expose a backside of the first and second epitaxial source/drain features; and
forming a bottom dielectric layer on the backside of the first and second epitaxial source/drain features.

14. The method of claim 13, further comprising forming a backside source/drain contact in the bottom dielectric layer, and the backside source/drain contact being electrically connected to the first epitaxial source/drain feature.

15. The method of claim 14, wherein the backside source/drain contact has a platform, a height of the platform relative to a top surface of the backside source/drain contact is less than a height of the bottom dielectric layer.

16. The method of claim 14, wherein the backside source/drain contact has a T-shaped profile.

17. The method of claim 14, further comprising filling an isolation insulating material on a backside of the second source/drain epitaxial feature, and the isolation insulating material covering the bottom dielectric layer.

18. The method of claim 13, further comprising forming a backside source/drain contact in the bottom dielectric layer, the backside source/drain contact being electrically connected to a bottom surface of the first epitaxial source/drain feature and a bottom surface of the second epitaxial source/drain feature.

19. The method of claim 18, wherein the backside source/drain contact has a π-shaped profile.

20. The method of claim 18, further comprising filling an isolation insulating material on a backside of the bottom dielectric layer, and the isolation insulating material covering the bottom dielectric layer.
